(19) United States
(12) Patent Application Publication
(10) Pub. No.: US 2012/0275106 A1
(43) Pub. Date: Nov. 1, 2012

(54) Hard Disk Drives With Integrated Mechanisms for Coupling of the Hard Disk Drive Within a Computing Environment and Related Methods

(75) Inventor: James E. McGuire, JR., Westerville, OH (US)

(73) Assignee: ENTROTECH, INC., Columbus, OH (US)

(21) Appl. No.: 13/096,712

(22) Filed: Apr. 28, 2011

(51) Int. Cl. H05K 7/00; H05K 13/00; G11B 5/82

(52) U.S. Cl. 361/679.33; 360/135; 29/592.1; G9B/5.293

(57) ABSTRACT

A hard disk drive of the invention comprises: a housing comprising a base, a cover, and at least one integrated coupling mechanism within a non-metallic portion of the housing for coupling of the hard disk drive within a computing environment; at least one disk for storage of data enclosed within the housing; and one or more electrical components enclosed within the housing for facilitating reading and recording of data at a desired location on the at least one disk contained within the housing. Methods of forming and hard disk drive rack assemblies comprising hard disk drives of the invention are also disclosed.

### BACKGROUND OF THE INVENTION

The present invention relates generally to hard disk drives with integrated mechanisms for coupling of the hard disk drive within a computing environment and related methods.

A disk drive is a device used to store information in a computing environment. In a disk drive, data is generally recorded on planar, round, rotating surfaces (which are commonly referred to as disks, discs, or platters). There are several types of disk drives, including optical disk drives, floppy disk drives, and hard disk drives. Nowadays, hard disk drives tend to be most common. Strictly speaking, “drive” refers to a device distinct from its medium, such as a tape drive and its tape, or a floppy disk drive and its floppy disk. A hard disk drive (sometimes referred to as a HDD), also referred to as a hard drive, hard disk, or fixed disk drive, is a non-volatile storage device that stores digitally encoded data on rapidly rotating platters with magnetic surfaces. Early hard disk drives had removable media; however, a HDD today is typically an encased unit with fixed media. Within a computing environment, multiple hard disk drives are often connected within a rack.

A typical hard disk drive includes a head disk assembly (HDA) and a printed circuit board assembly (PCBA) attached to a disk drive base of the HDA. The HDA typically includes at least one magnetic disk, a spindle motor for rotating the disk, and a head stack assembly (HSA) having an actuator assembly with at least one transducer head, typically several, for reading and writing data from the disk. The PCBA includes a servo control system in the form of a disk controller for generating servo control signals. The HSA is controllably positioned in response to the generated servo control signals from the disk controller. In so doing, the attached heads are moved relative to tracks disposed upon the disk. The heads are typically distanced from the magnetic disk by a gaseous cushion—so that they are said to “fly” over the disk. Thus, it is important that the position of the heads be well-controlled for proper reading and writing from the disk.

Effective and well-controlled positioning of components within a hard disk drive is more challenging when the hard disk drive is operating with mechanical components spinning therein. Instability (i.e., positional instability) between components in the hard disk drive often leads to introduction of problematic vibrations arising from rotation of disks within the hard disk drive. Undesirable harmonics from such vibrations become even more evident upon operation of multiple hard disk drives connected within a rack assembly. In order to facilitate positional stability, the base of a hard disk drive housing to which mechanical components are attached is conventionally made from rigid metal.

While the use of metal components undesirably increases the overall weight of an apparatus, use of metal components has been conventionally mandated in the hard disk drive industry due to the relative rigidity of metal components and other considerations. One additional consideration involves the sensitivity of mechanical spinning components therein to electromagnetic interference. Without mechanical spinning components therein, however, manufacturers of flash drives have taken advantage of the benefits of, for example, a plastic case for enclosure of the drive. See, for example, U.S. Pat. No. 7,301,776, which describes how metal material used for top and bottom plates of the drives described therein can be replaced by plastic as there are fewer materials-related issues associated with flash memory devices as compared to mechanical spinning hard disk drives.

In view of the number of potential problems impacting effective and long-term performance of hard disk drives, alternative methods and apparatus for improved hard disk drives and hard disk drive rack assemblies are desired. Most desired are those methods and apparatus with improved efficiency and reliability over conventional attempts to provide the same.

### SUMMARY OF THE INVENTION

A hard disk drive of the invention comprises: a housing comprising a base, a cover, and at least one integrated coupling mechanism within a non-metallic portion of the housing for coupling of the hard disk drive within a computing environment; at least one disk for storage of data enclosed within the housing; and one or more electrical components enclosed within the housing for facilitating reading and recording of data at a desired location on the at least one disk contained within the housing. According to one aspect of the invention, the integrated coupling mechanism is formed in a molded material. In one embodiment, the base comprises the integrated coupling mechanism. In another embodiment, the cover comprises the integrated coupling mechanism.

In one embodiment, the base comprises plastic. In another embodiment, the cover comprises plastic. In a further embodiment, each of the base and the cover comprises plastic.

In one embodiment, the integrated coupling mechanism is configured to mate with at least one mechanical fastener to which it can be securely coupled. In an exemplary embodiment, the integrated coupling mechanism comprises a female-type connector suitable for engagement with a male-type connector. In another exemplary embodiment, the integrated coupling mechanism comprises a male-type connector suitable for engagement with a female-type connector. An exemplary female-type connector comprises a threaded bore. An exemplary male-type connector comprises a screw.

A method of forming a hard disk drive of the invention comprises steps of: forming the housing in multiple components, wherein one of the multiple components comprises the integrated coupling mechanism; securing the integrated coupling mechanism within the housing; and assembling the housing around the one or more electrical components to form the hard disk drive. In one embodiment, the housing comprises a non-metallic housing.

In one embodiment, the integrated coupling mechanism is individually molded. According to a further embodiment, the integrated coupling mechanism is insert-molded within at least one other component of the housing during its formation.

In one embodiment, the integrated coupling mechanism is secured within the housing an adhesive. In another embodiment, the integrated coupling mechanism is secured within the housing a containing lip in the housing surrounding the integrated coupling mechanism.

According to another method of forming a hard disk drive of the invention, the method comprises steps of: molding at least one component of the housing to simultaneously form the integrated coupling mechanism therein; and assembling the housing around the one or more electrical components to form the hard disk drive. In one embodiment, the component of the housing is plastic, which is molded by injection molding.

Hard disk drive rack assemblies of the invention comprise at least one hard disk drive, preferably at least two hard disk drives, of the invention. In one embodiment, a hard disk drive rack assembly comprises multiple hard disk drives, wherein the hard disk drive of the invention comprises a majority of the hard disk drives therein. In a further embodiment, each of the hard disk drives therein comprises a hard disk drive of the invention.

### BRIEF DESCRIPTION OF THE DRAWINGS

Note that the components and features illustrated in all figures throughout this application are not necessarily drawn to scale and are understood to be variable in relative size and placement. Similarly, orientation of many of the components and features within the figures can vary such that, for example, a horizontal configuration could be readily reoriented to a vertical configuration, and vice versa, as desired.

FIG. 1 is a partial perspective view of a prior art hard disk drive with the top cover of the drive housing removed to illustrate certain features.

FIG. 2A is a top perspective view of a hard disk drive comprising two integrated coupling mechanisms according to the invention.

FIG. 2B is a partial side view of the hard disk drive of FIG. 2A.

FIG. 2C is a top perspective view of an alternate embodiment of the hard disk drive of FIG. 2A.

FIG. 2D is a partial side view of the hard disk drive of FIG. 2C.

FIG. 2E is a partial perspective view of a hard disk drive rack assembly comprising the hard disk drive of FIG. 2A.

### DETAILED DESCRIPTION OF THE PREFERRED EMBODIMENTS OF THE INVENTION

The present invention is beneficially applied in conjunction with any suitable conventional hard disk drive or hard disk drive rack assembly in need of performance improvements. A hard disk drive conventionally includes a base to which various components of the disk drive are mounted. A top cover cooperates with the base to form a housing that defines an encased environment for the hard disk drive. Any hard disk drive comprises any of a number of suitable components encased within the housing. The components within the hard disk drive include, for example, a spindle motor, which rotates one or more magnetic disks at a constant high speed, and an actuator assembly for writing information to and reading information from circular tracks on the disks. The actuator assembly typically includes a plurality of actuator arms extending towards the disks, with one or more flexures extending from each of the actuator arms. Mounted at the distal end of each of the flexures is a read/write head, which includes an air bearing slider enabling the head to fly in close proximity above the corresponding surface of the associated disk during operation of the hard disk drive. When the hard disk drive is powered down, the heads may be moved to a landing zone at an innermost region of the disks where the air bearing sliders are allowed to land on the disk surface as the disks stop rotating. Alternatively, the actuator assembly may move (unload) the heads beyond the outer circumference of the disks so that the heads are supported away from the disk surface by a load/unload ramp when the drive is powered down.

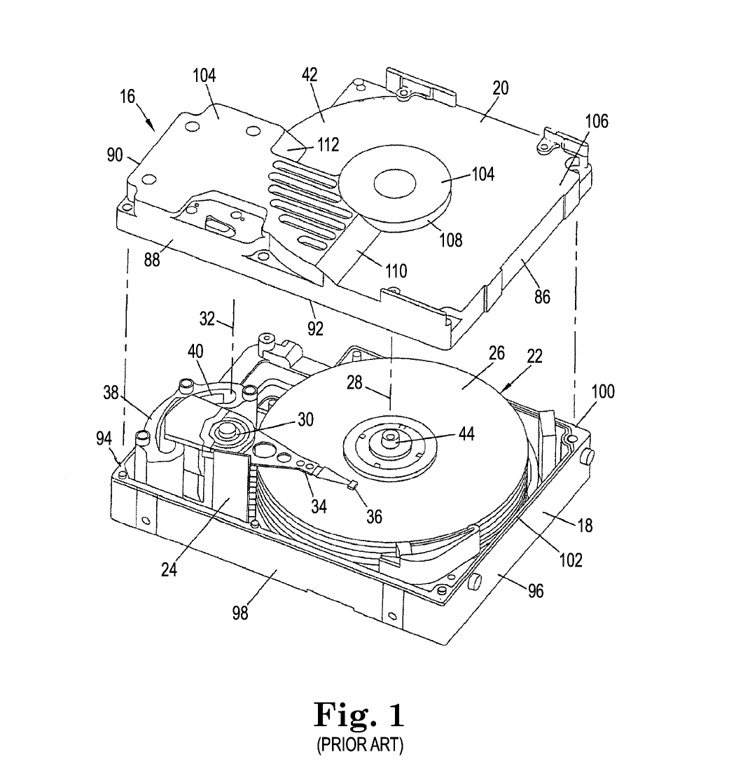

Turning now to the drawings, there is shown in FIG. 1 part of a prior art hard disk drive 16 described in U.S. Patent Publication No. 2003/0223148. The prior art hard disk drive 16 illustrated in FIG. 1 is only one example of many well-known embodiments of hard disk drives and is illustrated to show exemplary components of hard disk drives for use as a reference in conjunction with a description of the present invention. Recognize, however, that many conventional hard disk drives can be modified for improved coupling within a computing environment according to the improvements of the invention.

As shown in FIG. 1, a conventional hard disk drive 16 has a rigid outer housing including a base 18 and a cover 20. In FIG. 1, the cover 20 is removed from the base 18 to reveal a disk pack or spindle assembly 22 and a rotary actuator 24, both of which are mounted moveably with respect to the housing formed by the base 18 and cover 20. More particularly, the spindle assembly 22 includes a top disk 26 and several additional concentrically stacked and spaced-apart disks rotatable about a vertical spindle axis 28.

Rotary actuator 24 includes an actuator shaft 30 mounted to pivot relative to the base 18 about a vertical actuator axis 32. Several transducer support arms, including a top support arm 34, are fixed to rotate with the actuator shaft 30. Each arm carries a magnetic data transducing head—e.g., a transducing head 36 on a support arm 34. The rotary actuator 24 pivots to move the transducing head 36 along arcuate paths generally radially with respect to the disks. Selective actuator 24 pivoting, in combination with controlled rotation of the disks, allows reading and recording of data at any desired location at any one of the disk recording surfaces. Rotary actuator 24 is pivoted by selective application of an electrical current to a voice coil 38 supported for arcuate movement within a magnetic field created by a permanent magnet arrangement 40, which includes several magnets and a poll piece (both of which are not illustrated in further detail).

The rotary actuator 24 and spindle assembly 22 are supported between two opposed housing walls, including a top wall 42 of the cover 20 and a bottom wall of the base 18. Spindle shaft 44 and the actuator shaft 30 may be stationary—meaning that they are integral with the housing—with the disks and support arms being mounted to rotate relative to their respective shafts.

The cover 20 includes a vertical continuous sidewall structure including a rearward wall 86, a sidewall 88, and a forward wall 90. Here, the upper sidewall structure includes a generally flat, horizontal continuous bottom edge 92, though some embodiments may include a flange or other mated fitting so as to fit into a top edge 100 of base 18 facilitating a tight fit and/or laser-welding. The base 18 includes an upright wall structure including a forward wall 94, a rearward wall 96, and two opposed sidewalls, one of which is shown at 98. These walls combine to form a continuous, horizontal top edge 100. FIG. 1 also illustrates an elastomeric gasket seal 102 mounted to top edge 100 of the base 18. When the cover 20 is assembled onto the base 18, the confronting bottom edge 92 of the cover 20 and the top edge 100 of the base 18 are brought into sealing engagement to close the housing about the spindle assembly 22 and the rotary actuator 24.

The upper and lower sidewalls 88, 98 are generally relatively thick to lend rigidity to the housing. The top wall 42 of the cover 20 may be formed with a horizontal full height region 104 and a horizontal recessed region 106, the two types of regions being interconnected by several non-horizontal regions as indicated at 108, 110 and 112. One portion of the full height region 104 accommodates the rotary actuator 24 and the spindle assembly 22. The non-horizontal regions 108, 110, 112 provide additional stiffness to the top wall 42 of the cover 20, which strengthens the top wall 42 and enables a somewhat reduced thickness wall construction.

Hard disk drives of the invention comprise at least one integrated mechanism for coupling of the hard disk drive in a computing environment. In an exemplary embodiment, the hard disk drive comprises a non-metallic housing. It is to be understood that non-metallic hard disk drive housings may include metal, but such metal is only included in a minor proportion as compared to the housing in its entirety. Non-metallic housings afford many advantages as compared to metallic housings, some of which are described further below. Thus, due to the advantages afforded thereby, focus of the description of the invention is on its implementation in hard disk drives comprising non-metallic housings.

Several advantages are obtained by fabricating a hard disk drive housing, or individual components thereof (e.g., a base or a cover), from non-metallic materials that are lighter in weight than metal. Such lighter weight materials include, for example, ceramics, plastics, and many composites (e.g., glass-filled particulate plastics). The lighter weight provided by these materials translates into lighter weight assemblies including the hard disk drive, which makes for not only often more desirable features for the user of such assemblies but also beneficially reduces manufacturing and shipping costs associated with such assemblies. In an exemplary embodiment, at least one component of the hard disk drive housing comprises plastic. Suitable plastic materials include, for example, polycarbonate and polybutylterepthalate.

As a further example of the advantages of non-metallic materials, many of which are moldable, use of moldable materials facilitates design flexibility in that many performance-enhancing features can be directly molded within components of the housing. Examples of such features and hard disk drives comprising non-metallic housings are described in co-pending U.S. patent application Ser. No. 13/096,480, entitled “Metal-Coated Hard Disk Drives and Related Methods,” which is incorporated by reference herein in its entirety. In accordance with the present invention, at least one integrated mechanism for coupling of the hard disk drive in a computing environment can be efficiently molded within one or more individual components of the housing when they are formed from moldable materials.

Conventionally, hard disk drives are coupled in a framework (e.g., rack assembly) within a computing environment for operation with other electrical components to perform data functions. Often, hard disk drives are attached via screws to rails supporting one or more hard disk drives within a rack assembly. In order to decrease problematic vibrations arising from rotation of disks within the hard disk drive, which vibrations often become even more evident upon operation of multiple hard disk drives coupled within a rack assembly, attempts to provide vibration-damping rack assemblies have included fabricating such rack assemblies from specialized composite materials with vibration-damping qualities. Advantageously, use of such specialized materials, which are relatively expensive, is not necessary when implementing the present invention.

According to one embodiment of the invention, at least one integrated coupling mechanism is provided within a housing of a hard disk drive for coupling of the hard disk drive within a computing framework. In order to decrease propagation of vibrations within a rack assembly comprising more than one hard disk drive, at least one hard disk drive therein comprises at least one integrated coupling mechanism according to the invention. Preferably, a majority of the hard disk drives therein comprises at least one integrated coupling mechanism according to the invention. More preferably, each of the hard disk drives therein comprises at least one integrated coupling mechanism according to a further embodiment.

At least one integrated coupling mechanism of the invention is formed in a non-metallic portion of the hard disk drive housing. The non-metallic portion of the hard disk drive housing may be, for example, a plastic or elastomer. Therefore, advantageously, when coupling the hard disk drive within a computing environment, metal-to-metal attachments and problematic vibrations associated therewith are avoided according to the invention.

Preferably, for processing efficiency, the non-metallic portion of the housing comprises a molded material. According to one aspect of this embodiment, the non-metallic portion of the housing comprising the at least one integrated coupling mechanism is integrally molded with the housing. That is, the non-metallic portion of the housing comprising the at least one integrated coupling mechanism is molded simultaneously with the housing.

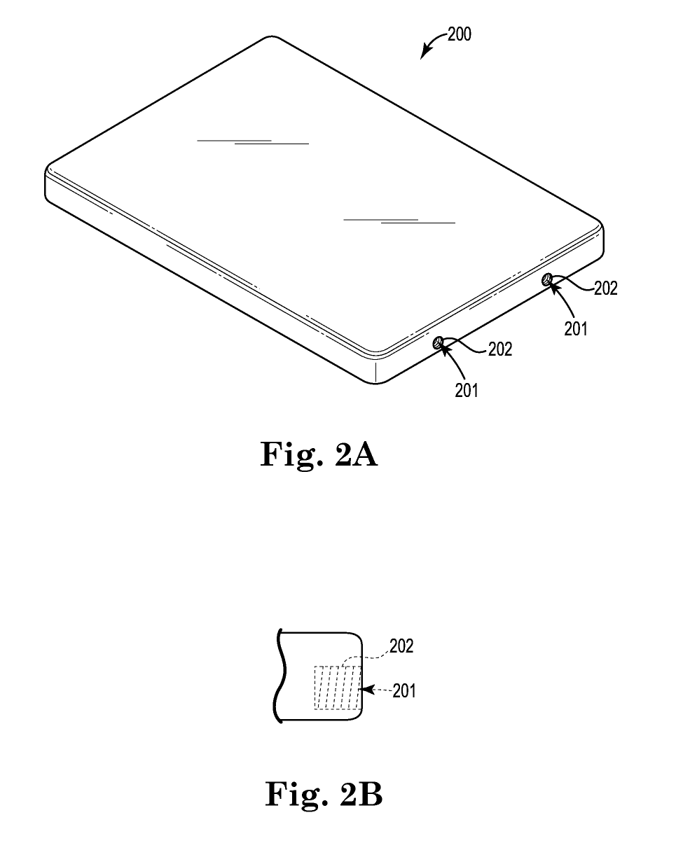

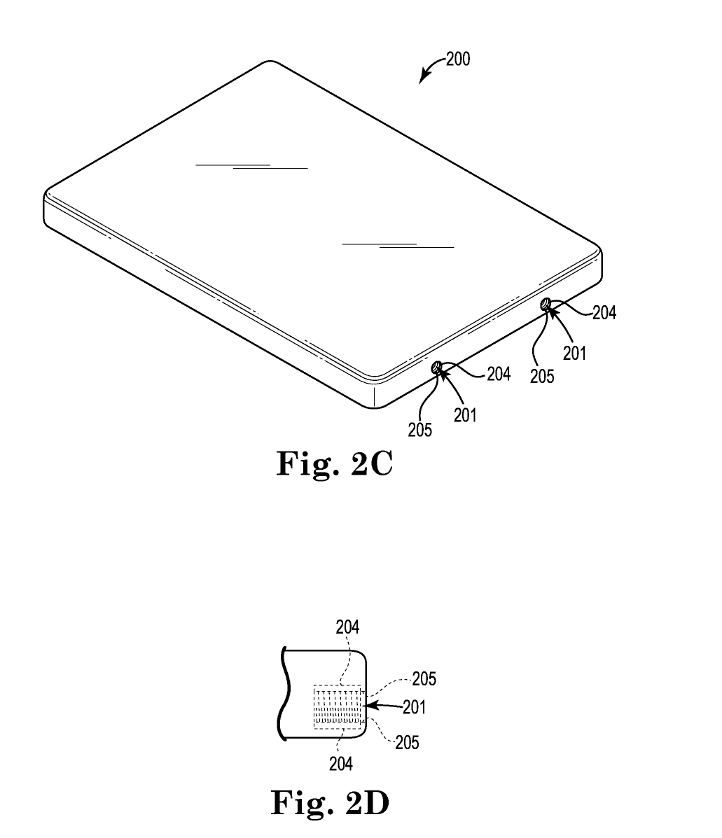

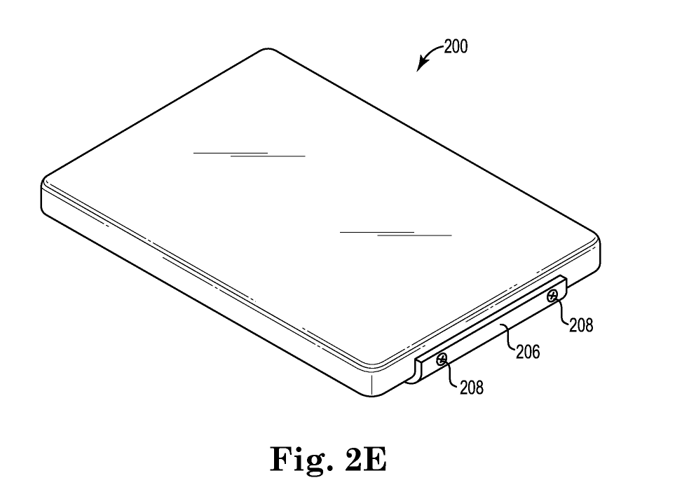

An exemplary aspect of this embodiment is illustrated in FIGS. 2A-2B, where two integrated coupling mechanisms 201 are integrally formed within the housing of the hard disk drive 200. Each integrated coupling mechanism 201 comprises a threaded bore 202. When coupled within a hard disk drive rack assembly, as illustrated in FIG. 2E, the hard disk drive 200 is coupled to a rail 206 within the rack assembly using a screw 208 inserted into each threaded bore 202.

According to another aspect of this embodiment, the non-metallic portion of the housing comprising the at least one integrated coupling mechanism is formed separately from the remainder of the housing component in which it is placed. According to one variable aspect of this embodiment, the non-metallic portion of the housing comprising the at least one integrated coupling mechanism is individually formed (e.g., by molding or otherwise) and then placed within the already formed remainder of the housing. For example, the non-metallic portion of the housing comprising the at least one integrated coupling mechanism is secured within the remainder of the housing any suitable apparatus and methodology, which include securing the same with an adhesive and/or mechanical apparatus (e.g., a containing lip in the remainder of the housing surrounding the integrated coupling mechanism).

According to another variable aspect of this embodiment, the non-metallic portion of the housing comprising the at least one integrated coupling mechanism is individually formed (e.g., by molding or otherwise) and then placed so that it positioned within the remainder of the housing during its formation. For example, the non-metallic portion of the housing comprising the at least one integrated coupling mechanism can be insert-molded within the remainder of the housing during its formation.

An exemplary aspect of this embodiment is illustrated in FIGS. 2C-2D, where two integrated coupling mechanisms 201 are integrally formed within the housing of the hard disk drive 200. Each integrated coupling mechanism 201 comprises a threaded insert 204 that can be, for example, insert-molded within the housing. A lip 205 in the housing surrounding the integrated coupling mechanism 201 secures the integrated coupling mechanism in the hard disk drive 200. When coupled within a hard disk drive rack assembly, as illustrated in FIG. 2E, the hard disk drive 200 is coupled to a rail 206 within the rack assembly using a screw 208 inserted into each threaded bore 202.

Integrated coupling mechanisms of the invention comprise any suitable configuration for coupling of the hard disk drive within a computing environment, e.g., within a hard disk drive rack assembly. In one embodiment, the integrated coupling mechanism is configured to mate with at least one mechanical fastener to which it can be securely coupled. For example, the integrated coupling mechanism can be a female-type connector (e.g., threaded bore) for engagement with a male-type connector (e.g., screw) or the integrated coupling mechanism can be a male-type connector for engagement with a female-type connector. Advantageously, when hard disk drives of the invention are coupled within a hard disk drive rack assembly, propagation of vibrations through the point of attachment introduced by the integrated coupling mechanism are minimized as compared to increased propagation of vibrations through conventional metal-to-metal attachment mechanisms.

Various modifications and alterations of the invention will become apparent to those skilled in the art without departing from the spirit and scope of the invention, which is defined by the accompanying claims. It should be noted that steps recited in any method claims below do not necessarily need to be performed in the order that they are recited. Those of ordinary skill in the art will recognize variations in performing the steps from the order in which they are recited. Further, while the present invention has been described with respect to a hard disk drive, it should be understood that the present invention also finds utility in other data storage devices—e.g., optical and magneto-optical storage devices.

1. A hard disk drive comprising
a housing comprising a base, a cover, and at least one integrated coupling mechanism within a non-metallic portion of the housing for coupling of the hard disk drive within a computing environment;
at least one disk for storage of data enclosed within the housing; and
one or more electrical components enclosed within the housing for facilitating reading and recording of data at a desired location on the at least one disk contained within the housing.

2. The hard disk drive of claim 1, wherein the base comprises plastic.

3. The hard disk drive of claim 1, wherein the cover comprises plastic.

4. The hard disk drive of claim 1, wherein each of the base and the cover comprises plastic.

5. The hard disk drive of claim 1, wherein the base comprises the integrated coupling mechanism.

6. The hard disk drive of claim 1, wherein the cover comprises the integrated coupling mechanism.

7. The hard disk drive of claim 1, wherein the non-metallic portion of the housing comprises a molded material.

8. The hard disk drive of claim 1, wherein the integrated coupling mechanism is configured to mate with at least one mechanical fastener to which it can be securely coupled.

9. The hard disk drive of claim 1, wherein the integrated coupling mechanism comprises a female-type connector suitable for engagement with a male-type connector.

10. The hard disk drive of claim 9, wherein the female-type connector comprises a threaded bore.

11. The hard disk drive of claim 9, wherein the male-type connector comprises a screw.

12. The hard disk drive of claim 1, wherein the integrated coupling mechanism comprises a male-type connector suitable for engagement with a female-type connector.

13. The hard disk drive of claim 1, wherein the integrated coupling mechanism comprises an elastomer.

14. A method of forming the hard disk drive of claim 1, comprising steps of:
forming the housing in multiple components, wherein one of the multiple components comprises the integrated coupling mechanism;
securing the integrated coupling mechanism within the housing; and
assembling the housing around the one or more electrical components to form the hard disk drive.

15. The method of claim 14, wherein the integrated coupling mechanism is individually molded.

16. The method of claim 14, wherein the integrated coupling mechanism is secured within the housing an adhesive.

17. The method of claim 14, wherein the integrated coupling mechanism is secured within the housing a containing lip in the housing surrounding the integrated coupling mechanism.

18. The method of claim 14, wherein the integrated coupling mechanism is insert-molded within at least one other component of the housing during its formation.

19. The method of claim 14, wherein the housing comprises a non-metallic housing.

20. A method of forming the hard disk drive of claim 1, comprising steps of:
molding at least one component of the housing to simultaneously form the integrated coupling mechanism therein; and
assembling the housing around the one or more electrical components to form the hard disk drive.

21. The method of claim 20, wherein the component of the housing is plastic, which is molded by injection molding.

22. A hard disk drive rack assembly, wherein the rack assembly comprises at least one of the hard disk drives of claim 1.

23. A hard disk drive rack assembly, wherein the rack assembly comprises at least two of the hard disk drives of claim 1.

24. A hard disk drive rack assembly comprising multiple hard disk drives, wherein the hard disk drive of claim 1 comprises a majority of the hard disk drives therein.

25. A hard disk drive rack assembly comprising multiple hard disk drives, wherein each of the hard disk drives therein comprises the hard disk drive of claim 1.
